(19) United States
(12) Patent Application Publication
(10) Pub. No.: US 2007/0157960 A1
(43) Pub. Date: Jul. 12, 2007

(54) Composite oxide having n-type thermoelectric conversion property

(75) Inventor: Ryoji Funahashi, Osaka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NAT'L INSTITUTE OF ADVANCED INDUSTRIAL SCIENCE & T, Tokyo (JP)

(21) Appl. No.: 10/577,916

(22) PCT Filed: Oct. 27, 2004
(86) PCT No.: PCT/JP04/15921

§ 371 Date: May 1, 2006

(30) Foreign Application Priority Data
Nov. 7, 2003 (JP) 2003-377708

(51) Int. Cl. H01L 35/16

(52) U.S. Cl. 136/238

(57) ABSTRACT

The present invention provides a complex oxide having a composition represented by the formula LaᵥM¹_{w}NiₓM²_{y}O_{z}; wherein M¹ is at least one element selected from the group consisting of Na, K, Sr, Ca, Bi and Nd; M² is at least one element selected from the group consisting of Ti, V, Cr, Mn, Fe, Co and Cu; and the subscripts are numbers which respectively satisfy 0.5≦v≦1.2; 0≦w≦0.5; 0.5≦x≦1.2; 0.01 ≦y≦0.5; and 2.8≦z≦3.2. The complex oxide of the invention has a negative Seebeck coefficient and a low electrical resistivity, i.e., an electrical resistivity of 10 mΩcm or less, at 100° C. or higher and is a novel material with an excellent performance as an n-type thermoelectric material.

### TECHNICAL FIELD

The present invention relates to a complex oxide with excellent performance as an n-type thermoelectric material, an n-type thermoelectric material using the complex oxide, and a thermoelectric module.

### BACKGROUND ART

In Japan, only 30% of the primary energy supply is used as effective energy, with about 70% being eventually lost to the atmosphere as heat. The heat generated by combustion in industrial plants, garbage-incineration facilities or the like is lost to the atmosphere without conversion into other energy. In this way, a vast amount of thermal energy is wastefully discarded, while acquiring only a small amount of energy by combustion of fossil fuels or other means.

To increase the proportion of energy to be utilized, the thermal energy currently lost to the atmosphere should be effectively used. For this purpose, thermoelectric conversion, which directly converts thermal energy to electrical energy, is an effective means. Thermoelectric conversion, which utilizes the Seebeck effect, is an energy conversion method for generating electricity by creating a difference in temperature between both ends of a thermoelectric material to produce a difference in electric potential. In such a method for generating electricity utilizing thermoelectric conversion, i.e., thermoelectric generation, electricity is generated simply by setting one end of a thermoelectric material at a location heated to a high temperature by waste heat, and the other end in the atmosphere (room temperature) and connecting conductive wires to both ends. This method entirely eliminates the need for moving parts such as the motors or turbines generally required for electric power generation. As a consequence, the method is economical and can be carried out without generating gases by combustion. Moreover, the method can continuously generate electricity until the thermoelectric material has deteriorated.

Therefore, thermoelectric generation is expected to play a role in the resolution of future energy problems. To realize thermoelectric generation, it is necessary to supply large amounts of a thermoelectric material that has a high thermoelectric conversion efficiency and excellent heat resistance, chemical durability, etc.

CoO₂-based layered oxides such as Ca₃Co₄O₉ have been reported as substances that achieve excellent thermoelectric performance in air at high temperatures (e.g., Japanese Patent Nos. 3069701, 3089301, and 3472814; Japanese Unexamined Patent Publication No. 2001-223393; and International Publication No. WO03/000605, etc.). However, all such oxides have p-type thermoelectric properties, and are materials with a positive Seebeck coefficient, i.e., materials in which the portion located at the high-temperature side has a low electric potential.

To produce a thermoelectric module using thermoelectric conversion, not only a p-type thermoelectric material but also an n-type thermoelectric material is needed. In such circumstances, the development of n-type thermoelectric materials is expected that are composed of low toxic and abundantly available elements, have excellent heat resistances, chemical durabilities, etc., and have high thermoelectric conversion efficiencies.

It has been reported that oxides obtained by partially substituting a certain site of complex oxides such as LaNiO₃, La₂NiO₄, etc. by Bi or like elements have n-type thermoelectric properties (Japanese Unexamined Patent Publication No. 2003-282964). For the practical use of thermoelectric generation, the development of n-type thermoelectric materials with more excellent thermoelectric conversion efficiency is desired.

### DISCLOSURE OF THE INVENTION

Problem to be Solved by the Invention

A principal object of the invention is to provide a novel material with excellent performance as an n-type thermoelectric material.

Means for Solving the Problem

The present inventors conducted extensive research to achieve the above object and found that a complex oxide having a specific composition comprising La, Ni and O as essential elements and partially substituted by specific elements has a negative Seebeck coefficient and a low electrical resistance, thus possessing excellent properties as an n-type thermoelectric material. The invention has been accomplished based on these findings.

The present invention provides the following complex oxides and n-type thermoelectric materials comprising the complex oxides.

Item 1. A complex oxide having a composition represented by the formula LaᵥM¹_{w}NiₓM²_{y}O_{z}; wherein M¹ is at least one element selected from the group consisting of Na, K, Sr, Ca, Bi and Nd; M² is at least one element selected from the group consisting of Ti, V, Cr, Mn, Fe, Co and Cu; and the subscripts are numbers which respectively satisfy 0.5≦v≦1.2; 0≦w≦0.5; 0.5≦x≦1.2; 0.01≦y≦0.5; and 2.8≦z≦3.2, the complex oxide having a negative Seebeck coefficient at 100° C. or higher.

Item 2. A complex oxide having a composition represented by the formula LaᵥM¹_{w}NiₓM²_{y}O_{z}; wherein M¹ is at least one element selected from the group consisting of Na, K, Sr, Ca, Bi and Nd; M² is at least one element selected from the group consisting of Ti, V, Cr, Mn, Fe, Co and Cu; and the subscripts are numbers which respectively satisfy 0.5≦v≦1.2; 0≦w≦0.5; 0.5≦x≦1.2; 0.01≦y≦0.5; and 2.8≦z≦3.2, the complex oxide having an electrical resistivity of 10 mΩcm or less at 100° C. or higher.

Item 3. An n-type thermoelectric material comprising the complex oxide of Item 1.

Item 4. An n-type thermoelectric material comprising the complex oxide of Item 2.

Item 5. A thermoelectric module comprising the n-type thermoelectric material of Item 3.

Item 6. A thermoelectric module comprising the n-type thermoelectric material of Item 4.

The complex oxide of the invention is a complex oxide whose composition is represented by the formula LaᵥM¹_{w}NiₓM²_{y}O_{z}.

In the formula, M¹ is at least one element selected from the group consisting of Na, K, Sr, Ca, Bi and Nd; M² is at least one element selected from the group consisting of Ti, V, Cr, Mn, Fe, Co and Cu. The subscripts are numbers which respectively satisfy 0.5≦v≦1.2; 0≦w≦0.5; 0.5≦x≦1.2; 0.01≦y≦0.5; and 2.8≦z≦3.2.

The above-described complex oxides have negative Seebeck coefficients and exhibit properties as n-type thermoelectric materials in that when a difference in temperature is created between both ends of the material comprising the oxide material, the electric potential generated by the thermoelectromotive force is higher at the high-temperature side than at the low-temperature side. More specifically, such complex oxides have a negative Seebeck coefficient at 100° C. or higher.

Furthermore, such complex oxides have good electrical conductivity and low electrical resistivity, and more specifically, an electrical resistivity of 10 mΩcm or less at 100° C. or higher.

FIG. 1 shows the X-ray diffraction pattern of the complex oxide obtained in Example 1 given below. The X-ray diffraction pattern shows that the complex oxide of the invention has a perovskite-type crystal structure.

FIG. 2 schematically shows the crystal structure of the complex oxides of the invention. As shown in FIG. 2, the complex oxides of the invention have a perovskite-type LaNiO₃ structure in which the La site is either not substituted or is partially substituted by M¹ and the Ni site is partially substituted by M².

There are no limitations on the methods for producing the complex oxides of the invention insofar as a single crystal or a polycrystal having the above-mentioned composition can be produced.

Crystalline complex oxides having the above-specified composition can be produced by known methods. Examples of known methods include single crystal-producing methods such as flux methods, zone-melting methods, crystal pulling methods, glass annealing methods via glass precursor, and the like; powder-producing methods such as solid phase reaction methods, sol-gel methods, and the like; film-forming methods such as sputtering methods, laser ablation methods, chemical vapor deposition methods, and the like; etc.

As an example, a process for preparing the complex oxide according to one of the solid phase reaction methods among the above methods is described below in detail.

The above-described complex oxides can be produced by, for example, mixing starting materials in the corresponding proportions to the proportions of the elemental components of the desired complex oxide, and sintering.

The sintering temperature and the sintering time are not limited as long as the desired complex oxide can be obtained. For example, sintering may be conducted at about 700° C. to about 1200° C. for about 10 to about 40 hours. When carbonates, organic compounds, or the like are used as starting materials, such starting materials are preferably decomposed by calcination prior to sintering, and then sintered to give the desired complex oxide. For example, when carbonates are used as a starting material, they may be calcined at about 700° C. to about 900° C. for about 10 hours, and then sintered under the above-mentioned conditions. Sintering means are not limited, and any means may be used, including electric furnaces and gas furnaces. Usually, sintering may be conducted in an oxidizing atmosphere such as in an oxygen stream or air. When the starting materials contain a sufficient amount of oxygen, sintering in, for example, an inert atmosphere is also possible. The amount of oxygen in the complex oxide to be produced can be controlled by adjusting the partial pressure of oxygen during sintering, sintering temperature, sintering time, etc. The higher the partial pressure of oxygen is, the higher the oxygen ratio in the above formulae can be. For the preparation of a desired complex oxide according to a solid phase reaction method, it is preferable to prepare a press-molded product from a starting material and then sinter the molded product so that the solid phase reaction can proceed efficiently. In this case, the sintered product may be crushed to prepare a powdery material with an appropriate particle size.

The starting materials are not limited insofar as they can produce oxides when sintered, and for example, metals, oxides, various compounds (e.g., carbonates, etc.) or the like can be used. Examples of usable sources of La are lanthanum oxide (La₂O₃), lanthanum carbonate (La₂(CO₃)₃), lanthanum nitrate (La(NO₃)₃), lanthanum chloride (LaCl₃), lanthanum hydroxide (La(OH)₃), lanthanum alkoxides (such as trimethoxylanthanum (La(OCH₃)₃), triethoxylanthanum (La(OC₂H₅)₃) and tripropoxylanthanum (La(OC₃H₇)₃), and the like. Examples of usable sources of Ni are nickel oxide (NiO), nickel nitrate (Ni(NO₃)₂), nickel chloride (NiCl₂), nickel hydroxide (Ni(OH)₂), nickel alkoxides (such as dimethoxynickel (Ni(OCH₃)₂), diethoxynickel (Ni(OC₂H₅)₂) and dipropoxynickel (Ni(OC₃H₇)₂), and the like. Similarly, examples of usable sources of other elements are oxides, chlorides, carbonates, nitrates, hydroxides, alkoxides and the like. Compounds containing two or more constituent elements of the complex oxide of the invention are also usable.

The desired complex oxides can also be obtained in the similar manner as above, using as a starting material an aqueous solution in which raw materials are dissolved. In this case, water-soluble compounds, such as nitrates and the like, may be used as raw materials. Such raw materials are dissolved to form an aqueous solution so as to have a metal component molar ratio of La:M¹:Ni:M² of 0.5-1.2:0-0.5:0.5-1.2:0.01-0.5. The obtained solution may be heated under stirring, for example, in an alumina crucible to evaporate water. The residue is heated at a temperature of about 600° C. to about 800° C. in air for about 10 hours to obtain calcined powder. Then, the calcined powder is sintered in the same manner as in the above-described method.

The thus obtained complex oxides of the invention have a negative Seebeck coefficient and a low electrical resistivity, i.e., an electrical resistivity of 10 mΩcm or less, at 100° C. or higher, so that the oxides exhibit excellent thermoelectric conversion properties as n-type thermoelectric materials. Furthermore, the complex oxides are excellent in both heat resistance and chemical durability and are composed of low-toxicity elements. Therefore, the complex oxides are highly practical as thermoelectric conversion materials.

The complex oxides of the invention with such properties can be effectively used as n-type thermoelectric materials in air at high temperatures.

FIG. 3 is a schematic representation of a thermoelectric module produced using a thermoelectric material comprising the complex oxide of the invention as its n-type thermoelectric elements. The thermoelectric module has a similar structure to conventional thermoelectric modules and comprises a high-temperature side substrate 1, a low-temperature side substrate 2, p-type thermoelectric materials 3, n-type thermoelectric materials 4, electrodes 5, and conductive wires 6. In such a module, the complex oxide of the invention is used as an n-type thermoelectric material.

### EFFECT OF THE INVENTION

The complex oxides of the invention have a negative Seebeck coefficient and a low electrical resistivity and are also excellent in terms of heat resistance, chemical durability, etc.

The complex oxides of the invention with such properties can be effectively utilized as n-type thermoelectric materials in air at high temperatures, whereas such use is impossible with conventional intermetallic compounds. Accordingly, a thermoelectric module comprising the complex oxides of the invention as n-type thermoelectric elements makes it possible to effectively utilize thermal energy heretofore lost to the atmosphere.

### BRIEF DESCRIPTION OF THE DRAWINGS

FIG. 1 shows the X-ray diffraction pattern of the complex oxide obtained in Example 1.

FIG. 2 schematically shows the crystal structure of the complex oxide of the invention.

FIG. 3 is a view schematically showing a thermoelectric module comprising the complex oxide of the invention as a thermoelectric material.

FIG. 4 is a graph showing the temperature dependency of the Seebeck coefficient of the complex oxides obtained in Example 1 and Comparative Example.

FIG. 5 is a graph showing the temperature dependency of the electrical resistivity of the complex oxides obtained in Example 1 and Comparative Example.

FIG. 6 is a graph showing the temperature dependency of the power factor of the complex oxides obtained in Example 1 and Comparative Example.

### DESCRIPTION OF REFERENCE NUMERALS

1. substrate of high-temperature side
2. substrate of low-temperature side
3. p-type thermoelectric material
4. n-type thermoelectric material
5. electrode
6. conductive wire

### BEST MODE FOR CARRYING OUT THE INVENTION

Examples are given below to illustrate the invention in further detail.

### Example 1

Using lanthanum nitrate (La₂(NO₃)₃.6H₂O) as a source of La, nickel nitrate (Ni(NO₃)₂.6H₂O) as a source of Ni, and copper nitrate (Cu(NO₃)₂.3H₂O) as a source of Cu, these starting materials were completely dissolved in distilled water in a La:Ni:Cu ratio (element ratio) of 1:0.8:0.2, sufficiently stirred and mixed in a crucible of alumina, and then heated to evaporate water for solidification. Subsequently, the residue was calcined at 600° C. in air using an electric furnace for 10 hours to decompose the nitrates. Thereafter, the calcinate was milled and molded by pressing, followed by sintering in an oxygen stream at 1000° C. for 20 hours to prepare a complex oxide.

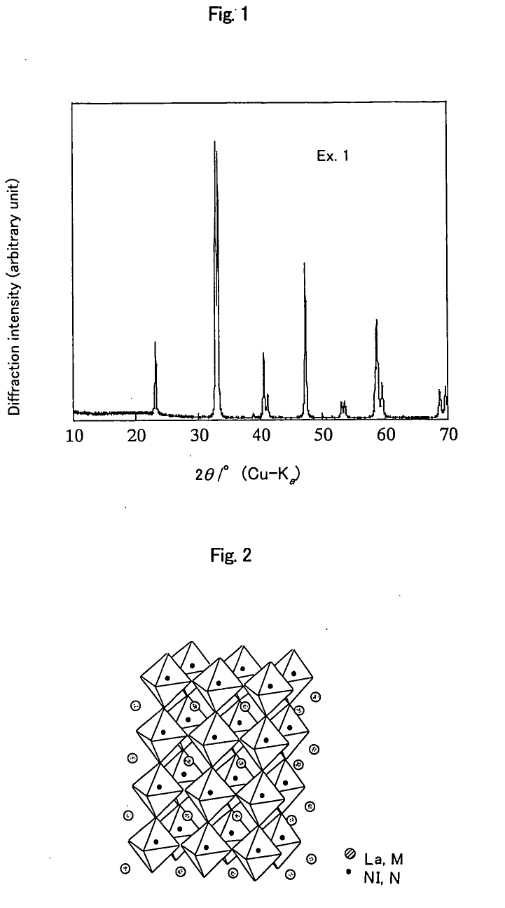

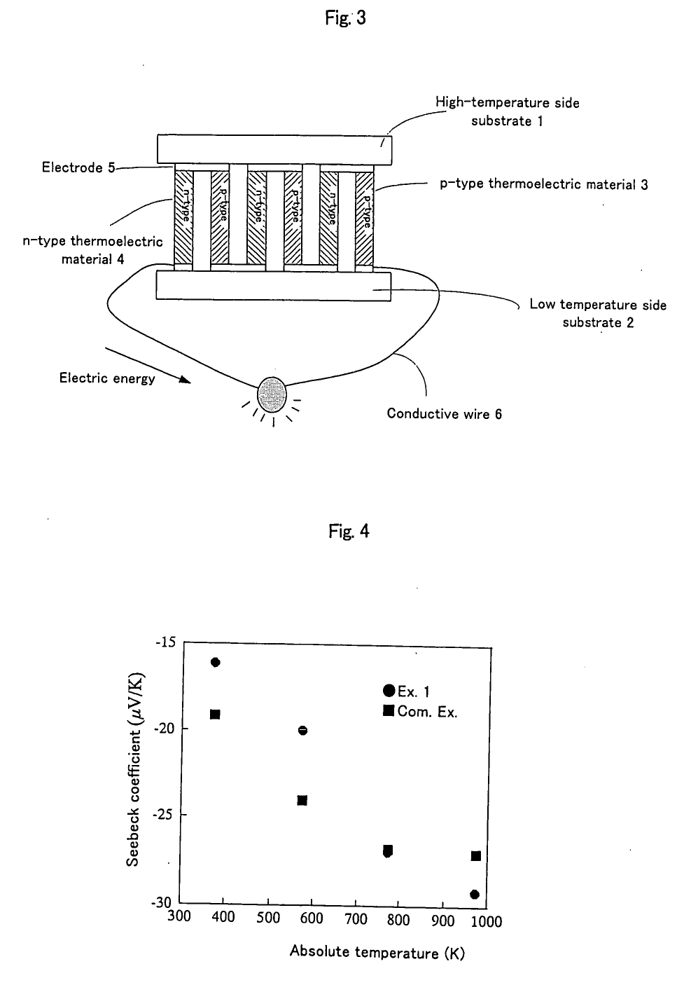

The complex oxide thus obtained had a composition represented by the formula LaNi_{0.8}Cu_{0.2}O_{3.1}, and showed the X-ray diffraction pattern as shown in FIG. 1.

FIG. 4 is a graph showing the temperature dependency of the Seebeck coefficient (S) of the obtained complex oxide over the temperature range of 100° C. to 700° C. (373 K to 973 K). It is apparent from FIG. 4 that the complex oxide has a negative Seebeck coefficient at 100° C. (373 K) or higher, thus being confirmed to be an n-type thermoelectric material in which the high-temperature side has a high electric potential. FIG. 4 also shows the measurement result of the Seebeck coefficient of LaNiO₃ as Comparative Example. Although the complex oxide obtained in Ex. 1 did not show a considerable increase in the Seebeck coefficient as compared with that of the complex oxide obtained in the Comparative example, the complex oxides obtained in the Examples described below showed noticeable increases in their Seebeck coefficients, depending on the type of substituent element. Note that, in all the Examples described below, the Seebeck coefficient at 100° C. or higher was negative.

FIG. 5 is a graph showing the temperature dependency of the electrical resistivity (ρ) of the complex oxide. FIG. 5 demonstrates that the complex oxide shows a low electrical resistivity, i.e., an electrical resistivity of about 10 mΩcm or less, over the temperature range of 100° C. to 700° C. (373 K to 973 K). FIG. 5 also shows the measurement result of the electrical resistivity of LaNiO₃ as Comparative Example. A comparison of the electrical resistivity of the complex oxide in Example 1 with that of the complex oxide of the Comparative Example shows that the electrical resistivity of the complex oxide of Example 1 is notably lower.

In all the Examples described below, the electrical resistivity was 10 mΩcm or less over the temperature range of 100° C. to 700° C. (373 K to 973 K).

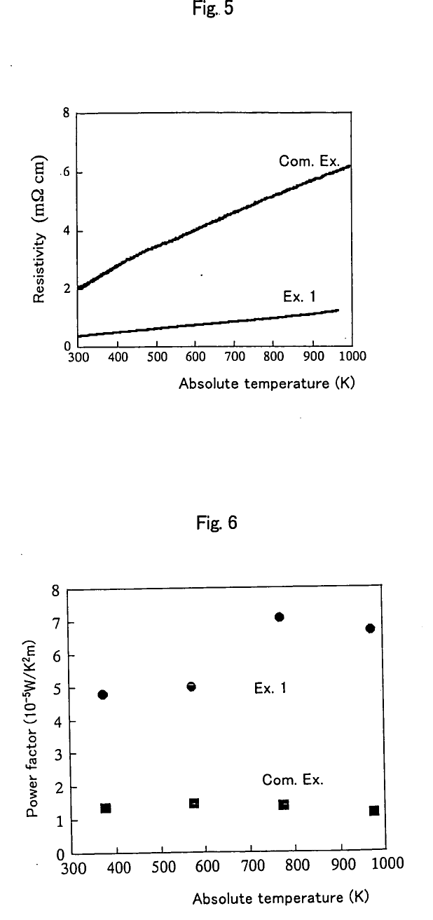

FIG. 6 is a graph showing the temperature dependency of the power factor (S²/ρ) of the complex oxides of Example 1 and the Comparative Example. As can be seen from FIG. 6, the complex oxide of Example 1 shows a higher power factor than the complex oxide (LaNiO₃) of the Comparative Example. In all the Examples described below, the power factor was higher than that of the complex oxide (LaNiO₃) of the Comparative Example.

### Examples 2-380

Starting materials were mixed to form aqueous solutions in such a manner as to yield the element ratios shown in Tables 1 to 19. Using the aqueous solutions obtained, the same procedure as in Example 1 was then conducted to provide complex oxides.

The sintering temperature and period were controlled in such a manner as to provide the desired complex oxides.

Tables 1 to 19 below show the element ratios of the obtained complex oxides, their Seebeck coefficients at 700° C., their electrical resistivities at 700° C., and their power factors at 700° C.

TABLE 1
La_{0.8-1.2}M¹₀Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 1 | Cu | 1.0:0.8:0.2:3.1 | −29 | 1.1 | 7.6 |
| 2 | Cu | 1.0:1.2:0.01:3.1 | −25 | 1.2 | 5.20 |
| 3 | Cu | 1.0:0.9:0.1:3.0 | −28 | 1.0 | 7.8 |
| 4 | Cu | 1.2:0.5:0.5:2.8 | −31 | 0.9 | 10.6 |
| 5 | Ti | 1.0:1.2:0.01:3.1 | −32 | 1.4 | 7.3 |
| 6 | Ti | 1.0:0.9:0.1:3.2 | −29 | 1.9 | 4.4 |
| 7 | V | 1.0:1.2:0.01:3.0 | −28 | 1.5 | 5.2 |
| 8 | V | 1.0:0.9:0.1:3.1 | −25 | 2.4 | 2.6 |
| 9 | Cr | 1.0:1.2:0.01:2.9 | −32 | 1.8 | 5.7 |
| 10 | Cr | 1.0:0.9:0.1:3.2 | −35 | 2.0 | 6.1 |
| 11 | Mn | 1.0:1.2:0.01:3.0 | −29 | 1.0 | 8.4 |
| 12 | Mn | 1.0:0.9:0.1:3.1 | −32 | 1.4 | 7.3 |
| 13 | Mn | 0.8:0.8:0.2:3.2 | −31 | 1.8 | 5.3 |
| 14 | Mn | 1.2:0.5:0.5:2.8 | −28 | 2.2 | 3.6 |
| 15 | Fe | 1.0:1.2:0.01:2.9 | −27 | 1.2 | 6.1 |
| 16 | Fe | 1.0:0.9:0.1:3.0 | −30 | 1.3 | 6.9 |
| 17 | Fe | 1.0:0.8:0.2:3.1 | −31 | 1.6 | 6.0 |
| 18 | Co | 1.0:1.2:0.01:3.2 | −27 | 1.2 | 6.1 |
| 19 | Co | 1.0:0.9:0.1:3.0 | −26 | 1.4 | 4.8 |
| 20 | Co | 1.0:0.8:0.2:3.1 | −29 | 2.0 | 4.2 |

TABLE 2
La_{0.8-1.2}Na_{0.1}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 21 | Cu | 1.2:1.2:0.01:3.2 | −29 | 1.1 | 7.6 |
| 22 | Cu | 0.9:0.8:0.2:3.0 | −31 | 1.3 | 7.4 |
| 23 | Cu | 0.8:0.5:0.5:2.8 | −27 | 1.2 | 6.1 |
| 24 | Cu | 0.9:0.9:0.1:2.9 | −30 | 1.0 | 9.0 |
| 25 | Ti | 0.9:0.8:0.1:3.1 | −27 | 1.5 | 4.9 |
| 26 | Ti | 0.9:0.6:0.5:3.0 | −28 | 2.1 | 3.7 |
| 27 | V | 0.9:0.8:0.1:3.1 | −25 | 1.2 | 5.2 |
| 28 | V | 0.9:0.6:0.5:3.0 | −26 | 1.9 | 3.6 |
| 29 | Cr | 0.9:0.8:0.1:3.1 | −31 | 1.5 | 6.4 |
| 30 | Cr | 0.9:0.6:0.5:3.0 | −35 | 2.4 | 5.1 |
| 31 | Mn | 1.2:1.2:0.01:3.2 | −27 | 1.4 | 5.2 |
| 32 | Mn | 0.9:0.8:0.2:3.0 | −30 | 1.3 | 6.9 |
| 33 | Mn | 0.8:0.5:0.5:2.8 | −25 | 1.8 | 3.5 |
| 34 | Mn | 0.9:0.9:0.1:2.9 | −28 | 1.2 | 6.5 |
| 35 | Fe | 0.9:0.9:0.1:3.1 | −35 | 1.3 | 9.4 |
| 36 | Fe | 0.8:0.8:0.2:2.9 | −30 | 1.5 | 6.0 |
| 37 | Fe | 1.0:0.5:0.5:3.0 | −32 | 2.2 | 4.7 |
| 38 | Co | 0.9:0.9:0.1:3.1 | −30 | 1.2 | 7.5 |
| 39 | Co | 0.8:0.8:0.2:2.9 | −29 | 1.0 | 8.4 |
| 40 | Co | 1.0:0.5:0.5:3.0 | −35 | 1.9 | 6.4 |

TABLE 3
La_{0.8-1.2}K_{0.1}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 41 | Cu | 1.2:1.2:0.01:3.2 | −28 | 1.0 | 7.8 |
| 42 | Cu | 0.9:0.8:0.2:3.0 | −30 | 0.9 | 10 |
| 43 | Cu | 0.8:0.5:0.5:2.8 | −32 | 1.1 | 9.3 |
| 44 | Cu | 0.9:0.9:0.1:2.9 | −30 | 1.2 | 7.5 |
| 45 | Ti | 0.9:0.8:0.1:3.1 | −29 | 1.8 | 4.7 |
| 46 | Ti | 0.9:0.6:0.5:3.0 | −28 | 2.4 | 3.3 |
| 47 | V | 0.9:0.8:0.1:3.1 | −27 | 1.5 | 4.9 |
| 48 | V | 0.9:0.6:0.5:3.0 | −27 | 2.2 | 3.3 |
| 49 | Cr | 0.9:0.8:0.1:3.1 | −29 | 1.3 | 6.5 |
| 50 | Cr | 0.9:0.6:0.5:3.0 | −40 | 1.9 | 8.4 |
| 51 | Mn | 1.2:1.2:0.01:3.2 | −32 | 1.0 | 10.2 |
| 52 | Mn | 0.9:0.8:0.2:3.0 | −30 | 1.3 | 6.9 |
| 53 | Mn | 0.8:0.5:0.5:2.8 | −27 | 2.0 | 3.6 |
| 54 | Mn | 0.9:0.9:0.1:2.9 | −29 | 1.7 | 4.9 |
| 55 | Fe | 0.9:0.9:0.1:3.1 | −31 | 1.2 | 8.0 |
| 56 | Fe | 0.8:0.8:0.2:2.9 | −33 | 1.3 | 8.4 |
| 57 | Fe | 1.0:0.5:0.5:3.0 | −35 | 1.9 | 6.4 |
| 58 | Co | 0.9:0.9:0.1:3.1 | −29 | 1.0 | 8.4 |
| 59 | Co | 0.8:0.8:0.2:2.9 | −28 | 1.1 | 7.1 |
| 60 | Co | 1.0:0.5:0.5:3.0 | −27 | 1.8 | 4.1 |

TABLE 4
La_{0.8-1.2}Sr_{0.1}Ni_{0.5-1.2}M²_{0.01-0.5}O_{2.8-32}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 61 | Cu | 1.2:1.2:0.01:3.2 | −28 | 1.1 | 7.1 |
| 62 | Cu | 0.9:0.8:0.2:3.0 | −30 | 1.0 | 9.0 |
| 63 | Cu | 0.8:0.5:0.5:2.8 | −29 | 1.2 | 7.0 |
| 64 | Cu | 0.9:0.9:0.1:2.9 | −32 | 1.3 | 7.9 |
| 65 | Ti | 0.9:0.8:0.1:3.1 | −30 | 1.7 | 5.3 |
| 66 | Ti | 0.9:0.6:0.5:3.0 | −33 | 2.0 | 5.4 |
| 67 | V | 0.9:0.8:0.1:3.1 | −30 | 1.4 | 6.4 |
| 68 | V | 0.9:0.6:0.5:3.0 | −27 | 2.1 | 3.5 |
| 69 | Cr | 0.9:0.8:0.1:3.1 | −35 | 1.4 | 8.8 |
| 70 | Cr | 0.9:0.6:0.5:3.0 | −36 | 2.4 | 5.4 |
| 71 | Mn | 1.2:1.2:0.01:3.2 | −30 | 1.2 | 7.5 |
| 72 | Mn | 0.9:0.8:0.2:3.0 | −31 | 1.5 | 6.4 |
| 73 | Mn | 0.8:0.5:0.5:2.8 | −30 | 2.2 | 4.1 |
| 74 | Mn | 0.9:0.9:0.1:2.9 | −30 | 1.2 | 7.5 |
| 75 | Fe | 0.9:0.9:0.1:3.1 | −27 | 1.4 | 5.2 |
| 76 | Fe | 0.8:0.8:0.2:2.9 | −28 | 1.5 | 5.2 |
| 77 | Fe | 1.0:0.5:0.5:3.0 | −26 | 2.4 | 2.8 |
| 78 | Co | 0.9:0.9:0.1:3.1 | −27 | 1.2 | 6.1 |
| 79 | Co | 0.8:0.8:0.2:2.9 | −26 | 1.3 | 5.2 |
| 80 | Co | 1.0:0.5:0.5:3.0 | −25 | 1.9 | 3.3 |

TABLE 5
La_{0.8-1.2}Ca_{0.1}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 81 | Cu | 1.2:1.2:0.01:3.2 | −31 | 1.2 | 8.0 |
| 82 | Cu | 0.9:0.8:0.2:3.0 | −30 | 1.3 | 6.9 |
| 83 | Cu | 0.8:0.5:0.5:2.8 | −32 | 1.2 | 8.5 |
| 84 | Cu | 0.9:0.9:0.1:2.9 | −30 | 1.1 | 8.2 |
| 85 | Ti | 0.9:0.8:0.1:3.1 | −27 | 1.5 | 4.9 |
| 86 | Ti | 0.9:0.6:0.5:3.0 | −29 | 2.5 | 3.4 |
| 87 | V | 0.9:0.8:0.1:3.1 | −30 | 1.6 | 5.6 |
| 88 | V | 0.9:0.6:0.5:3.0 | −31 | 2.3 | 4.2 |
| 89 | Cr | 0.9:0.8:0.1:3.1 | −40 | 1.8 | 8.9 |
| 90 | Cr | 0.9:0.6:0.5:3.0 | −42 | 2.1 | 8.4 |
| 91 | Mn | 1.2:1.2:0.01:3.2 | −30 | 1.2 | 7.5 |
| 92 | Mn | 0.9:0.8:0.2:3.0 | −31 | 1.3 | 7.4 |
| 93 | Mn | 0.8:0.5:0.5:2.8 | −33 | 1.5 | 7.3 |
| 94 | Mn | 0.9:0.9:0.1:2.9 | −32 | 1.1 | 9.3 |
| 95 | Fe | 0.9:0.9:0.1:3.1 | −30 | 1.4 | 6.4 |
| 96 | Fe | 0.8:0.8:0.2:2.9 | −27 | 1.5 | 4.9 |
| 97 | Fe | 1.0:0.5:0.5:3.0 | −28 | 2.4 | 3.3 |
| 98 | Co | 0.9:0.9:0.1:3.1 | −27 | 1.2 | 6.1 |
| 99 | Co | 0.8:0.8:0.2:2.9 | −25 | 1.1 | 5.7 |
| 100 | Co | 1.0:0.5:0.5:3.0 | −26 | 1.9 | 3.6 |

TABLE 6
La_{0.8-1.2}Bi_{0.1}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 101 | Cu | 1.2:1.2:0.01:3.2 | −33 | 1.0 | 10.9 |
| 102 | Cu | 0.9:0.8:0.2:3.0 | −32 | 0.9 | 11.4 |
| 103 | Cu | 0.8:0.5:0.5:2.8 | −30 | 1.1 | 8.2 |
| 104 | Cu | 0.9:0.9:0.1:2.9 | −29 | 0.8 | 10.5 |
| 105 | Ti | 0.9:0.8:0.1:3.1 | −30 | 1.3 | 6.9 |
| 106 | Ti | 0.9:0.6:0.5:3.0 | −31 | 1.5 | 6.4 |
| 107 | V | 0.9:0.8:0.1:3.1 | −27 | 1.6 | 4.6 |
| 108 | V | 0.9:0.6:0.5:3.0 | −26 | 1.7 | 4.0 |
| 109 | Cr | 0.9:0.8:0.1:3.1 | −35 | 1.8 | 6.8 |
| 110 | Cr | 0.9:0.6:0.5:3.0 | −37 | 2.0 | 6.8 |
| 111 | Mn | 1.2:1.2:0.01:3.2 | −29 | 1.3 | 6.5 |
| 112 | Mn | 0.9:0.8:0.2:3.0 | −28 | 1.5 | 5.3 |
| 113 | Mn | 0.8:0.5:0.5:2.8 | −29 | 1.7 | 4.9 |
| 114 | Mn | 0.9:0.9:0.1:2.9 | −30 | 1.4 | 6.4 |
| 115 | Fe | 0.9:0.9:0.1:3.1 | −31 | 1.2 | 8.0 |
| 116 | Fe | 0.8:0.8:0.2:2.9 | −33 | 1.5 | 7.3 |
| 117 | Fe | 1.0:0.5:0.5:3.0 | −34 | 1.7 | 6.8 |
| 118 | Co | 0.9:0.9:0.1:3.1 | −30 | 1.2 | 7.5 |
| 119 | Co | 0.8:0.8:0.2:2.9 | −27 | 1.3 | 5.6 |
| 120 | Co | 1.0:0.5:0.5:3.0 | −29 | 1.6 | 5.3 |

TABLE 7
La_{0.8-1.2}Nd_{0.1}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 121 | Cu | 1.2:1.2:0.01:3.2 | −29 | 1.3 | 6.5 |
| 122 | Cu | 0.9:0.8:0.2:3.0 | −30 | 1.5 | 6.0 |
| 123 | Cu | 0.8:0.5:0.5:2.8 | −27 | 1.4 | 5.2 |
| 124 | Cu | 0.9:0.9:0.1:2.9 | −28 | 1.4 | 5.6 |
| 125 | Ti | 0.9:0.8:0.1:3.1 | −26 | 1.8 | 3.8 |
| 126 | Ti | 0.9:0.6:0.5:3.0 | −26 | 2.1 | 3.2 |
| 127 | V | 0.9:0.8:0.1:3.1 | −25 | 1.5 | 4.2 |
| 128 | V | 0.9:0.6:0.5:3.0 | −27 | 1.9 | 3.8 |
| 129 | Cr | 0.9:0.8:0.1:3.1 | −30 | 1.3 | 6.9 |
| 130 | Cr | 0.9:0.6:0.5:3.0 | −35 | 2.0 | 6.1 |
| 131 | Mn | 1.2:1.2:0.01:3.2 | −27 | 1.5 | 4.9 |
| 132 | Mn | 0.9:0.8:0.2:3.0 | −29 | 1.6 | 5.3 |
| 133 | Mn | 0.8:0.5:0.5:2.8 | −31 | 2.1 | 4.6 |
| 134 | Mn | 0.9:0.9:0.1:2.9 | −33 | 1.7 | 6.40 |
| 135 | Fe | 0.9:0.9:0.1:3.1 | −30 | 1.4 | 6.4 |
| 136 | Fe | 0.8:0.8:0.2:2.9 | −27 | 1.8 | 4.1 |
| 137 | Fe | 1.0:0.5:0.5:3.0 | −29 | 2.4 | 3.5 |
| 138 | Co | 0.9:0.9:0.1:3.1 | −31 | 1.7 | 5.7 |
| 139 | Co | 0.8:0.8:0.2:2.9 | −29 | 1.8 | 4.7 |
| 140 | Co | 1.0:0.5:0.5:3.0 | −35 | 2.4 | 5.1 |

TABLE 8
La_{0.8-1.0}Na_{0.2}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 141 | Cu | 1.0:1.2:0.01:3.2 | −27 | 2.0 | 3.6 |
| 142 | Cu | 0.9:0.8:0.2:3.0 | −30 | 2.3 | 3.9 |
| 143 | Cu | 0.8:0.5:0.5:2.8 | −27 | 2.5 | 2.9 |
| 144 | Cu | 0.9:0.9:0.1:2.9 | −28 | 2.6 | 3.0 |
| 145 | Ti | 0.9:0.8:0.1:3.1 | −25 | 3.0 | 2.1 |
| 146 | Ti | 0.9:0.6:0.5:3.0 | −26 | 3.5 | 1.9 |
| 147 | V | 0.9:0.8:0.1:3.1 | −27 | 3.0 | 2.4 |
| 148 | V | 0.9:0.6:0.5:3.0 | −30 | 3.6 | 2.5 |
| 149 | Cr | 0.9:0.8:0.1:3.1 | −37 | 3.2 | 4.3 |
| 150 | Cr | 0.9:0.6:0.5:3.0 | −38 | 3.7 | 3.9 |
| 151 | Mn | 1.0:12:0.01:3.2 | −27 | 3.0 | 2.4 |
| 152 | Mn | 0.9:0.8:0.2:3.0 | −25 | 3.5 | 1.8 |
| 153 | Mn | 0.8:0.5:0.5:2.8 | −26 | 3.6 | 1.9 |
| 154 | Mn | 0.9:0.9:0.1:2.9 | −24 | 3.8 | 1.5 |
| 155 | Fe | 0.9:0.9:0.1:3.1 | −30 | 4.0 | 2.3 |
| 156 | Fe | 0.8:0.8:0.2:2.9 | −31 | 4.2 | 2.3 |
| 157 | Fe | 1.0:0.5:0.5:3.0 | −32 | 4.1 | 2.5 |
| 158 | Co | 0.9:0.9:0.1:3.1 | −33 | 3.8 | 2.9 |
| 159 | Co | 0.8:0.8:0.2:2.9 | −32 | 3.5 | 2.9 |
| 160 | Co | 1.0:0.5:0.5:3.0 | −30 | 3.6 | 2.5 |

TABLE 9
La_{0.8-1.0}K_{0.2}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 161 | Cu | 1.0:1.2:0.01:3.2 | −34 | 2.1 | 5.5 |
| 162 | Cu | 0.9:0.8:0.2:3.0 | −30 | 3.0 | 3.0 |
| 163 | Cu | 0.8:0.5:0.5:2.8 | −29 | 3.5 | 2.4 |
| 164 | Cu | 0.9:0.9:0.1:2.9 | −29 | 2.7 | 3.1 |
| 165 | Ti | 0.9:0.8:0.1:3.1 | −27 | 2.4 | 3.0 |
| 166 | Ti | 0.9:0.6:0.5:3.0 | −28 | 3.6 | 2.2 |
| 167 | V | 0.9:0.8:0.1:3.1 | −30 | 2.9 | 3.1 |
| 168 | V | 0.9:0.6:0.5:3.0 | −35 | 3.8 | 3.2 |
| 169 | Cr | 0.9:0.8:0.1:3.1 | −39 | 2.5 | 6.1 |
| 170 | Cr | 0.9:0.6:0.5:3.0 | −25 | 3.2 | 2.0 |
| 171 | Mn | 1.0:12:0.01:3.2 | −30 | 2.7 | 3.3 |
| 172 | Mn | 0.9:0.8:0.2:3.0 | −32 | 2.6 | 3.9 |
| 173 | Mn | 0.8:0.5:0.5:2.8 | −33 | 3.9 | 2.8 |
| 174 | Mn | 0.9:0.9:0.1:2.9 | −35 | 2.7 | 4.5 |
| 175 | Fe | 0.9:0.9:0.1:3.1 | −29 | 2.3 | 3.7 |
| 176 | Fe | 0.8:0.8:0.2:2.9 | −28 | 2.5 | 3.1 |
| 177 | Fe | 1.0:0.5:0.5:3.0 | −32 | 3.9 | 2.6 |
| 178 | Co | 0.9:0.9:0.1:3.1 | −29 | 2.7 | 3.1 |
| 179 | Co | 0.8:0.8:0.2:2.9 | −30 | 2.4 | 3.8 |
| 180 | Co | 1.0:0.5:0.5:3.0 | −29 | 3.8 | 2.2 |

TABLE 10
La_{0.8-1.0}Sr_{0.2}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K (700° C.) |
| No. | M² | La:Ni:M²:O | (μVK⁻¹) | (mΩcm) | (10⁻⁵ W/K²m) |
| 181 | Cu | 1.0:1.2:0.01:3.2 | −29 | 2.4 | 3.5 |
| 182 | Cu | 0.9:0.8:0.2:3.0 | −31 | 3.6 | 2.7 |
| 183 | Cu | 0.8:0.5:0.5:2.8 | −27 | 3.9 | 1.9 |
| 184 | Cu | 0.9:0.9:0.1:2.9 | −26 | 2.8 | 2.4 |
| 185 | Ti | 0.9:0.8:0.1:3.1 | −28 | 2.7 | 2.9 |
| 186 | Ti | 0.9:0.6:0.5:3.0 | −30 | 3.4 | 2.6 |
| 187 | V | 0.9:0.8:0.1:3.1 | −25 | 3.0 | 2.1 |
| 188 | V | 0.9:0.6:0.5:3.0 | −32 | 3.6 | 2.8 |
| 189 | Cr | 0.9:0.8:0.1:3.1 | −30 | 2.9 | 3.1 |
| 190 | Cr | 0.9:0.6:0.5:3.0 | −38 | 3.2 | 4.5 |
| 191 | Mn | 1.0:1.2:0.01:3.2 | −27 | 2.7 | 2.7 |
| 192 | Mn | 0.9:0.8:0.2:3.0 | −20 | 3.0 | 1.3 |
| 193 | Mn | 0.8:0.5:0.5:2.8 | −29 | 3.7 | 2.3 |
| 194 | Mn | 0.9:0.9:0.1:2.9 | −30 | 3.2 | 2.8 |
| 195 | Fe | 0.9:0.9:0.1:3.1 | −27 | 3.0 | 2.4 |
| 196 | Fe | 0.8:0.8:0.2:2.9 | −24 | 3.4 | 1.7 |
| 197 | Fe | 1.0:0.5:0.5:3.0 | −31 | 3.8 | 2.5 |
| 198 | Co | 0.9:0.9:0.1:3.1 | −27 | 2.7 | 2.7 |
| 199 | Co | 0.8:0.8:0.2:2.9 | −28 | 3.0 | 2.6 |
| 200 | Co | 1.0:0.5:0.5:3.0 | −30 | 3.9 | 2.3 |

TABLE 11
La_{0.8-1.0}Ca_{0.2}Ni_{0.5-1.2}M²_{0.01-0.5}O_{2.8-3.2}

| | | | Seebeck | Electrical | |
|---|---|---|---|---|---|
| | | | coefficient | resistivity | Power factor |
| | | | 973 K (700° C.) | 973 K (700° C.) | 973 K (700° C.) |
| No. | M² | La:Ni:M²:O | (μVK⁻¹) | (mΩcm) | (10⁻⁵ W/K²m) |
| 201 | Cu | 1.0:1.2:0.01:3.2 | −29 | 2.1 | 4.0 |
| 202 | Cu | 0.9:0.8:0.2:3.0 | −30 | 3.2 | 2.8 |
| 203 | Cu | 0.8:0.5:0.5:2.8 | −27 | 4.0 | 1.8 |
| 204 | Cu | 0.9:0.9:0.1:2.9 | −29 | 2.1 | 4.0 |
| 205 | Ti | 0.9:0.8:0.1:3.1 | −31 | 2.0 | 4.8 |
| 206 | Ti | 0.9:0.6:0.5:3.0 | −29 | 3.9 | 2.2 |
| 207 | V | 0.9:0.8:0.1:3.1 | −30 | 3.2 | 2.8 |
| 208 | V | 0.9:0.6:0.5:3.0 | −32 | 3.7 | 2.8 |
| 209 | Cr | 0.9:0.8:0.1:3.1 | −29 | 3.0 | 2.8 |
| 200 | Cr | 0.9:0.6:0.5:3.0 | −39 | 3.8 | 4.0 |
| 211 | Mn | 1.0:1.2:0.01:3.2 | −29 | 2.7 | 3.1 |
| 212 | Mn | 0.9:0.8:0.2:3.0 | −30 | 3.5 | 2.6 |
| 213 | Mn | 0.8:0.5:0.5:2.8 | −33 | 3.9 | 2.8 |
| 214 | Mn | 0.9:0.9:0.1:2.9 | −30 | 3.0 | 3.0 |
| 215 | Fe | 0.9:0.9:0.1:3.1 | −27 | 3.1 | 2.4 |
| 216 | Fe | 0.8:0.8:0.2:2.9 | −28 | 3.4 | 2.3 |
| 217 | Fe | 1.0:0.5:0.5:3.0 | −33 | 3.8 | 2.9 |
| 218 | Co | 0.9:0.9:0.1:3.1 | −25 | 2.7 | 2.3 |
| 219 | Co | 0.8:0.8:0.2:2.9 | −29 | 3.0 | 2.8 |
| 220 | Co | 1.0:0.5:0.5:3.0 | −31 | 3.9 | 2.5 |

TABLE 12
La_{0.8-1.0}Bi_{0.2}Ni_{0.5-1.2}M²_{0.01-0.5}O_{2.8-3.2}

| | | | Seebeck | Electrical | |
|---|---|---|---|---|---|
| | | | coefficient | resistivity | Power factor |
| | | | 973 K (700° C.) | 973 K (700° C.) | 973 K (700° C.) |
| No. | M² | La:Ni:M²:O | (μVK⁻¹) | (mΩcm) | (10⁻⁵ W/K²m) |
| 221 | Cu | 1.0:1.2:0.01:3.2 | −28 | 2.1 | 3.7 |
| 222 | Cu | 0.9:0.8:0.2:3.0 | −30 | 2.5 | 3.6 |
| 223 | Cu | 0.8:0.5:0.5:2.8 | −37 | 3.0 | 4.6 |
| 224 | Cu | 0.9:0.9:0.1:2.9 | −29 | 2.6 | 3.2 |
| 225 | Ti | 0.9:0.8:0.1:3.1 | −27 | 3.2 | 2.3 |
| 226 | Ti | 0.9:0.6:0.5:3.0 | −30 | 4.0 | 2.3 |
| 227 | V | 0.9:0.8:0.1:3.1 | −31 | 3.1 | 3.1 |
| 228 | V | 0.9:0.6:0.5:3.0 | −35 | 4.1 | 3.0 |
| 229 | Cr | 0.9:0.8:0.1:3.1 | −29 | 3.7 | 2.3 |
| 230 | Cr | 0.9:0.6:0.5:3.0 | −38 | 4.4 | 3.3 |
| 231 | Mn | 1.0:1.2:0.01:3.2 | −27 | 2.9 | 2.5 |
| 232 | Mn | 0.9:0.8:0.2:3.0 | −29 | 3.6 | 2.3 |
| 233 | Mn | 0.8:0.5:0.5:2.8 | −34 | 4.7 | 2.5 |
| 234 | Mn | 0.9:0.9:0.1:2.9 | −29 | 3.3 | 2.5 |
| 235 | Fe | 0.9:0.9:0.1:3.1 | −27 | 2.8 | 2.6 |
| 236 | Fe | 0.8:0.8:0.2:2.9 | −28 | 3.5 | 2.2 |
| 237 | Fe | 1.0:0.5:0.5:3.0 | −34 | 4.1 | 2.8 |
| 238 | Co | 0.9:0.9:0.1:3.1 | −30 | 2.9 | 3.1 |
| 239 | Co | 0.8:0.8:0.2:2.9 | −35 | 3.0 | 4.1 |
| 240 | Co | 1.0:0.5:0.5:3.0 | −36 | 4.0 | 3.2 |

TABLE 13
La_{0.8-1.0}Nd_{0.2}Ni_{0.5-1.2}M²_{0.01-0.5}O_{2.8-3.2}

| | | | Seebeck | Electrical | |
|---|---|---|---|---|---|
| | | | coefficient | resistivity | Power factor |
| | | | 973 K (700° C.) | 973 K (700° C.) | 973 K (700° C.) |
| No. | M² | La:Ni:M²:O | (μVK⁻¹) | (mΩcm) | (10⁻⁵ W/K²m) |
| 241 | Cu | 1.0:1.2:0.01:3.2 | −29 | 1.9 | 4.4 |
| 242 | Cu | 0.9:0.8:0.2:3.0 | −31 | 2.2 | 4.4 |
| 243 | Cu | 0.8:0.5:0.5:2.8 | −33 | 3.1 | 3.5 |
| 244 | Cu | 0.9:0.9:0.1:2.9 | −29 | 2.3 | 3.7 |
| 245 | Ti | 0.9:0.8:0.1:3.1 | −28 | 2.2 | 3.6 |
| 246 | Ti | 0.9:0.6:0.5:3.0 | −35 | 3.8 | 3.2 |
| 247 | V | 0.9:0.8:0.1:3.1 | −27 | 2.1 | 3.5 |
| 248 | V | 0.9:0.6:0.5:3.0 | −28 | 4.0 | 2.0 |
| 249 | Cr | 0.9:0.8:0.1:3.1 | −28 | 2.3 | 3.4 |
| 250 | Cr | 0.9:0.6:0.5:3.0 | −37 | 4.5 | 3.0 |
| 251 | Mn | 1.0:1.2:0.01:3.2 | −29 | 2.8 | 3.0 |
| 252 | Mn | 0.9:0.8:0.2:3.0 | −32 | 3.0 | 3.4 |
| 253 | Mn | 0.8:0.5:0.5:2.8 | −34 | 4.1 | 2.8 |
| 254 | Mn | 0.9:0.9:0.1:2.9 | −30 | 3.0 | 3 |
| 255 | Fe | 0.9:0.9:0.1:3.1 | −29 | 2.7 | 3.1 |
| 256 | Fe | 0.8:0.8:0.2:2.9 | −30 | 3.1 | 2.9 |
| 257 | Fe | 1.0:0.5:0.5:3.0 | −37 | 4.5 | 3.0 |
| 258 | Co | 0.9:0.9:0.1:3.1 | −27 | 2.7 | 2.7 |
| 259 | Co | 0.8:0.8:0.2:2.9 | −28 | 3.9 | 2.0 |
| 260 | Co | 1.0:0.5:0.5:3.0 | −31 | 4.6 | 2.1 |

TABLE 14
La_{0.5-0.7}Na_{0.5}Ni_{0.5-1.2}M²_{0.01-0.5}O_{2.8-3.2}

| | | | Seebeck | Electrical | |
|---|---|---|---|---|---|
| | | | coefficient | resistivity | Power factor |
| | | | 973 K (700° C.) | 973 K (700° C.) | 973 K (700° C.) |
| No. | M² | La:Ni:M²:O | (μVK⁻¹) | (mΩcm) | (10⁻⁵ W/K²m) |
| 261 | Cu | 0.7:1.2:0.01:3.2 | −30 | 3.0 | 3.0 |
| 262 | Cu | 0.6:0.8:0.2:3.0 | −37 | 4.2 | 3.3 |
| 263 | Cu | 0.5:0.5:0.5:2.8 | −37 | 5.0 | 2.7 |
| 264 | Cu | 0.6:0.9:0.1:2.9 | −27 | 3.9 | 1.9 |
| 265 | Ti | 0.6:0.8:0.1:3.1 | −26 | 3.6 | 1.9 |
| 266 | Ti | 0.6:0.6:0.5:3.0 | −37 | 5.4 | 2.5 |
| 267 | V | 0.6:0.8:0.1:3.1 | −29 | 3.7 | 2.3 |
| 268 | V | 0.6:0.6:0.5:3.0 | −38 | 5.5 | 2.6 |
| 269 | Cr | 0.6:0.8:0.1:3.1 | −29 | 3.4 | 2.5 |
| 270 | Cr | 0.6:0.6:0.5:3.0 | −36 | 5.0 | 2.6 |
| 271 | Mn | 0.7:1.2:0.01:3.2 | −25 | 3.8 | 1.6 |
| 272 | Mn | 0.6:0.8:0.2:3.0 | −28 | 2.9 | 2.7 |
| 273 | Mn | 0.5:0.5:0.5:2.8 | −34 | 5.4 | 2.1 |
| 274 | Mn | 0.6:0.9:0.1:2.9 | −30 | 3.2 | 2.8 |
| 275 | Fe | 0.6:0.9:0.1:3.1 | −27 | 3.0 | 2.4 |
| 276 | Fe | 0.5:0.8:0.2:2.9 | −30 | 3.9 | 2.3 |
| 277 | Fe | 0.7:0.5:0.5:3.0 | −32 | 5.4 | 1.9 |
| 278 | Co | 0.6:0.9:0.1:3.1 | −29 | 3.7 | 2.3 |
| 279 | Co | 0.5:0.8:0.2:2.9 | −33 | 4.2 | 2.6 |
| 280 | Co | 0.7:0.5:0.5:3.0 | −37 | 5.1 | 2.7 |

TABLE 15
La_{0.5-0.7}K_{0.5}Ni_{0.5-1.2}M²_{0.01-0.5}O_{2.8-3.2}

| | | | Seebeck | Electrical | |
|---|---|---|---|---|---|
| | | | coefficient | resistivity | Power factor |
| | | | 973 K (700° C.) | 973 K (700° C.) | 973 K (700° C.) |
| No. | M² | La:Ni:M²:O | (μVK⁻¹) | (mΩcm) | (10⁻⁵ W/K²m) |
| 281 | Cu | 0.7:1.2:0.01:3.2 | −29 | 3.4 | 2.5 |
| 282 | Cu | 0.6:0.8:0.2:3.0 | −30 | 3.9 | 2.3 |
| 283 | Cu | 0.5:0.5:0.5:2.8 | −34 | 5.0 | 2.3 |
| 284 | Cu | 0.6:0.9:0.1:2.9 | −27 | 3.4 | 2.1 |
| 285 | Ti | 0.6:0.8:0.1:3.1 | −28 | 4.2 | 1.9 |
| 286 | Ti | 0.6:0.6:0.5:3.0 | −34 | 5.6 | 2.1 |
| 287 | V | 0.6:0.8:0.1:3.1 | −30 | 3.9 | 2.3 |
| 288 | V | 0.6:0.6:0.5:3.0 | −36 | 5.5 | 2.4 |
| 289 | Cr | 0.6:0.8:0.1:3.1 | −27 | 4.2 | 1.7 |
| 290 | Cr | 0.6:0.6:0.5:3.0 | −39 | 5.9 | 2.6 |
| 291 | Mn | 0.7:1.2:0.01:3.2 | −26 | 4.0 | 1.7 |
| 292 | Mn | 0.6:0.8:0.2:3.0 | −28 | 5.0 | 1.6 |
| 293 | Mn | 0.5:0.5:0.5:2.8 | −31 | 5.5 | 1.7 |
| 294 | Mn | 0.6:0.9:0.1:2.9 | −30 | 4.3 | 2.1 |
| 295 | Fe | 0.6:0.9:0.1:3.1 | −27 | 4.4 | 1.7 |
| 296 | Fe | 0.5:0.8:0.2:2.9 | −34 | 5.0 | 2.3 |
| 297 | Fe | 0.7:0.5:0.5:3.0 | −38 | 5.6 | 2.6 |
| 298 | Co | 0.6:0.9:0.1:3.1 | −29 | 4.3 | 2.0 |
| 299 | Co | 0.5:0.8:0.2:2.9 | −30 | 4.7 | 1.9 |
| 300 | Co | 0.7:0.5:0.5:3.0 | −40 | 5.4 | 3.0 |

TABLE 16
La_{0.5-0.7}Sr_{0.5}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K(700° C.) |
| No. | M² | La:Ni:M²:O | (μVK⁻¹) | (mΩcm) | (10⁻⁵ W/K⁻²m) |
| 301 | Cu | 0.7:1.2:0.01:3.2 | −27 | 4.1 | 1.8 |
| 302 | Cu | 0.6:0.8:0.2:3.0 | −30 | 4.2 | 2.1 |
| 303 | Cu | 0.5:0.5:0.5:2.8 | −27 | 5.1 | 1.4 |
| 303 | Cu | 0.6:0.9:0.1:2.9 | −29 | 4.0 | 2.1 |
| 305 | Ti | 0.6:0.8:0.1:3.1 | −30 | 3.9 | 2.3 |
| 306 | Ti | 0.6:0.6:0.5:3.0 | −34 | 5.7 | 2.0 |
| 307 | V | 0.6:0.8:0.1:3.1 | −29 | 4.2 | 2.0 |
| 308 | V | 0.6:0.6:0.5:3.0 | −32 | 5.5 | 1.9 |
| 309 | Cr | 0.6:0.8:0.1:3.1 | −31 | 5.0 | 1.9 |
| 310 | Cr | 0.6:0.6:0.5:3.0 | −38 | 5.9 | 2.4 |
| 311 | Mn | 0.7:1.2:0.01:3.2 | −27 | 3.8 | 1.9 |
| 312 | Mn | 0.6:0.8:0.2:3.0 | −26 | 4.2 | 1.6 |
| 313 | Mn | 0.5:0.5:0.5:2.8 | −28 | 5.6 | 1.4 |
| 314 | Mn | 0.6:0.9:0.1:2.9 | −27 | 4.7 | 1.6 |
| 315 | Fe | 0.6:0.9:0.1:3.1 | −29 | 3.9 | 2.2 |
| 316 | Fe | 0.5:0.8:0.2:2.9 | −30 | 4.4 | 2.0 |
| 317 | Fe | 0.7:0.5:0.5:3.0 | −39 | 5.9 | 2.6 |
| 318 | Co | 0.6:0.9:0.1:3.1 | −30 | 4.7 | 1.9 |
| 319 | Co | 0.5:0.8:0.2:2.9 | −29 | 5.0 | 1.7 |
| 320 | Co | 0.7:0.5:0.5:3.0 | −40 | 5.8 | 2.8 |

TABLE 17
La_{0.5-0.7}Ca_{0.5}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K(700° C.) |
| No. | M² | La:Ni:M²:O | (μVK⁻¹) | (mΩcm) | (10⁻⁵ W/K⁻²m) |
| 321 | Cu | 0.7:1.2:0.01:3.2 | −27 | 4.1 | 1.8 |
| 322 | Cu | 0.6:0.8:0.2:3.0 | −28 | 4.5 | 1.7 |
| 323 | Cu | 0.5:0.5:0.5:2.8 | −30 | 5.5 | 1.6 |
| 324 | Cu | 0.6:0.9:0.1:2.9 | −30 | 3.9 | 2.3 |
| 325 | Ti | 0.6:0.8:0.1:3.1 | −27 | 4.3 | 1.7 |
| 326 | Ti | 0.6:0.6:0.5:3.0 | −29 | 5.1 | 1.6 |
| 327 | V | 0.6:0.8:0.1:3.1 | −26 | 4.2 | 1.6 |
| 328 | V | 0.6:0.6:0.5:3.0 | −32 | 6.0 | 1.7 |
| 329 | Cr | 0.6:0.8:0.1:3.1 | −27 | 3.9 | 1.9 |
| 330 | Cr | 0.6:0.6:0.5:3.0 | −34 | 5.9 | 2.0 |
| 331 | Mn | 0.7:1.2:0.01:3.2 | −27 | 3.7 | 2.0 |
| 332 | Mn | 0.6:0.8:0.2:3.0 | −29 | 4.4 | 1.9 |
| 333 | Mn | 0.5:0.5:0.5:2.8 | −35 | 5.7 | 2.1 |
| 334 | Mn | 0.6:0.9:0.1:2.9 | −28 | 3.9 | 2.0 |
| 335 | Fe | 0.6:0.9:0.1:3.1 | −30 | 4.3 | 2.1 |
| 336 | Fe | 0.5:0.8:0.2:2.9 | −29 | 5.2 | 1.6 |
| 337 | Fe | 0.7:0.5:0.5:3.0 | −33 | 5.9 | 1.8 |
| 338 | Co | 0.6:0.9:0.1:3.1 | −27 | 3.8 | 1.9 |
| 339 | Co | 0.5:0.8:0.2:2.9 | −30 | 4.2 | 2.1 |
| 340 | Co | 0.7:0.5:0.5:3.0 | −39 | 5.5 | 2.8 |

TABLE 18
La_{0.5-0.7}Bi_{0.5}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K(700° C.) |
| No. | M² | La:Ni:M²:O | (μVK⁻¹) | (mΩcm) | (10⁻⁵ W/K⁻²m) |
| 341 | Cu | 0.7:1.2:0.01:3.2 | −29 | 3.9 | 2.2 |
| 342 | Cu | 0.6:0.8:0.2:3.0 | −30 | 4.7 | 1.9 |
| 343 | Cu | 0.5:0.5:0.5:2.8 | −30 | 5.8 | 1.6 |
| 344 | Cu | 0.6:0.9:0.1:2.9 | −33 | 4.2 | 2.6 |
| 345 | Ti | 0.6:0.8:0.1:3.1 | −26 | 4.4 | 1.5 |
| 346 | Ti | 0.6:0.6:0.5:3.0 | −30 | 5.6 | 1.6 |
| 347 | V | 0.6:0.8:0.1:3.1 | −30 | 5.5 | 1.6 |
| 348 | V | 0.6:0.6:0.5:3.0 | −37 | 6.8 | 2.0 |
| 349 | Cr | 0.6:0.8:0.1:3.1 | −35 | 4.5 | 2.7 |
| 350 | Cr | 0.6:0.6:0.5:3.0 | −40 | 6.0 | 2.7 |
| 351 | Mn | 0.7:1.2:0.01:3.2 | −27 | 4.0 | 1.8 |
| 352 | Mn | 0.6:0.8:0.2:3.0 | −28 | 4.9 | 1.6 |
| 353 | Mn | 0.5:0.5:0.5:2.8 | −30 | 5.8 | 1.6 |
| 354 | Mn | 0.6:0.9:0.1:2.9 | −24 | 4.7 | 1.2 |
| 355 | Fe | 0.6:0.9:0.1:3.1 | −27 | 4.4 | 1.7 |
| 356 | Fe | 0.5:0.8:0.2:2.9 | −29 | 4.9 | 1.7 |
| 357 | Fe | 0.7:0.5:0.5:3.0 | −35 | 6.3 | 1.9 |
| 358 | Co | 0.6:0.9:0.1:3.1 | −27 | 4.5 | 1.6 |
| 359 | Co | 0.5:0.8:0.2:2.9 | −26 | 5.5 | 1.2 |
| 360 | Co | 0.7:0.5:0.5:3.0 | −39 | 6.3 | 2.4 |

TABLE 19
La_{0.5-0.7}Nd_{0.5}Ni_{0.5-1.2}M²_{0.01-0.5}O_{2.8-3.2}

| | | | Seebeck | Electrical | |
|---|---|---|---|---|---|
| | | | coefficient | resistivity | |
| | | | 973 K | 973 K | Power factor |
| | | | (700° C.) | (700° C.) | 973 K(700° C.) |
| No. | M² | La:Ni:M²:O | (μVK⁻¹) | (mΩcm) | (10⁻⁵ W/K⁻²m) |
| 361 | Cu | 0.7:1.2:0.01:3.2 | −29 | 3.8 | 2.2 |
| 362 | Cu | 0.6:0.8:0.2:3.0 | −32 | 4.2 | 2.4 |
| 363 | Cu | 0.5:0.5:0.5:2.8 | −34 | 5.5 | 2.1 |
| 364 | Cu | 0.6:0.9:0.1:2.9 | −27 | 3.9 | 1.9 |
| 365 | Ti | 0.6:0.8:0.1:3.1 | −30 | 4.0 | 2.3 |
| 366 | Ti | 0.6:0.6:0.5:3.0 | −27 | 4.3 | 1.7 |
| 367 | V | 0.6:0.8:0.1:3.1 | −32 | 4.0 | 2.6 |
| 368 | V | 0.6:0.6:0.5:3.0 | −29 | 5.5 | 1.5 |
| 369 | Cr | 0.6:0.8:0.1:3.1 | −34 | 4.5 | 2.6 |
| 370 | Cr | 0.6:0.6:0.5:3.0 | −40 | 6.5 | 2.5 |
| 371 | Mn | 0.7:1.2:0.01:3.2 | −37 | 4.2 | 3.3 |
| 372 | Mn | 0.6:0.8:0.2:3.0 | −42 | 4.5 | 3.9 |
| 373 | Mn | 0.5:0.5:0.5:2.8 | −45 | 5.9 | 3.4 |
| 374 | Mn | 0.6:0.9:0.1:2.9 | −29 | 4.0 | 2.1 |
| 375 | Fe | 0.6:0.9:0.1:3.1 | −28 | 4.2 | 1.9 |
| 376 | Fe | 0.5:0.8:0.2:2.9 | −32 | 3.9 | 2.6 |
| 377 | Fe | 0.7:0.5:0.5:3.0 | −45 | 5.6 | 3.6 |
| 378 | Co | 0.6:0.9:0.1:3.1 | −27 | 3.6 | 2.0 |
| 379 | Co | 0.5:0.8:0.2:2.9 | −38 | 5.0 | 2.9 |
| 380 | Co | 0.7:0.5:0.5:3.0 | −29 | 5.9 | 1.4 |

1. A complex oxide having a composition represented by the formula LaᵥM¹_{w}NiₓM²_{y}O_{z}; wherein M¹ is at least one element selected from the group consisting of Na, K, Sr, Ca, Bi and Nd; M² is at least one element selected from the group consisting of Ti, V, Cr, Mn, Fe, Co and Cu; and the subscripts are numbers which respectively satisfy 0.5≦v≦1.2; 0≦w≦0.5; 0.5≦x≦1.2; 0.01≦y≦0.5; and 2.8≦z≦3.2, the complex oxide having a negative Seebeck coefficient at 100° C. or higher.

2. A complex oxide having a composition represented by the formula LaᵥM¹_{w}NiₓM²_{y}O_{z}; wherein M¹ is at least one element selected from the group consisting of Na, K, Sr, Ca, Bi and Nd; M² is at least one element selected from the group consisting of Ti, V, Cr, Mn, Fe, Co and Cu; and the subscripts are numbers which respectively satisfy 0.5≦v≦1.2; 0≦w≦0.5; 0.5≦x≦1.2; 0.01≦y≦0.5; and 2.8≦z≦3.2, the complex oxide having an electrical resistivity of 10 mΩcm or less at 100° C. or higher.

3. An n-type thermoelectric material comprising the complex oxide of claim 1.

4. An n-type thermoelectric material comprising the complex oxide of claim 2.

5. A thermoelectric module comprising the n-type thermoelectric material of claim 3.

6. A thermoelectric module comprising the n-type thermoelectric material of claim 4.
